(19) United States
(12) Patent Application Publication
(10) Pub. No.: US 2025/0176448 A1
(43) Pub. Date: May 29, 2025

(54) MONOLITHIC INTEGRATION OF MINIATURIZED CAPACITOR BANK WITH CHALCOGENIDE-BASED SWITCHES FOR ENERGY EFFICIENT RECONFIGURABLE INTELLIGENT SURFACES

(71) Applicant: Dell Products L.P., Round Rock, TX (US)

(72) Inventors: Tejinder Singh, Kanata (CA); Kan Wang, Ottawa (CA); Navjot Kaur Khaira, Kanata (CA); Morris Repeta, Ottawa (CA)

(21) Appl. No.: 18/523,446

(22) Filed: Nov. 29, 2023

(51) Int. Cl. H10N 79/00; H01L 23/66; H01P 3/00

(52) U.S. Cl. CPC H10N 79/00; H01L 23/66; H01P 3/003; H10D 1/68; H01L 2223/6627

(57) ABSTRACT

A reconfigurable intelligent surface is disclosed. The reconfigurable intelligent surface includes unit cells that include a bank of capacitors that is monolithically integrated into the structure of the reconfigurable intelligent surface. The bank of capacitors include a plurality of capacitors that have a high Self-Resonant Frequency (SRF). Each of the capacitors is integrated with a Phase Change Material (PCM) based switch.

### FIELD OF THE INVENTION

Embodiments of the present invention generally relate to reconfigurable intelligent surfaces. More particularly, at least some embodiments of the invention relate to systems, hardware, software, and methods for reconfigurable intelligent surfaces with a bank of capacitors that is monolithically integrated into the structure of the surface.

### BACKGROUND

Many operating networks are based on 5G technologies. Notwithstanding the benefits of 5G technologies, the demand for high-speed and reliable connectivity that will enable a wider range of applications such as autonomous vehicles, smart cities, Internet of Things (IoT) devices, augmented reality, and more continues to grow. Thus, the pursuit of newer technologies, such as 5G-Adv and 6G networks, continues. These networks are intended to provide faster data speeds, lower latencies, increased capacity, and better performance compared to earlier generations.

Software controlled metasurfaces, such as reconfigurable intelligent surfaces (RIS), have the ability to enhance the performance and capabilities of networks such as 5G-Adv. and 6G networks. A reconfigurable intelligent surface includes a number of small elements or units that can manipulate the propagation of electromagnetic waves. By intelligently adjusting the reflection and/or transmission properties of these elements, a reconfigurable intelligent surface can often redirect the wireless signals in desired directions.

The reconfigurability of a reconfigurable intelligent surface may be achieved with the assistance of surface mounted RF (Radio Frequency) components such as varactor diodes and PIN diodes. However, the use of surface mounted RF components such as varactor diodes and PIN diodes suffer from the following problems when implemented in a reconfigurable intelligent surface:

Limited frequency range: Many RF components are designed for specific frequency bands, which restricts their applicability for wideband reconfiguration in RIS. The technology is mature in lower frequency, but commonly suffers from low Self-Resonant Frequency (SRF) which severely degrade their performance and sometimes make them unusable in mmWave applications. Achieving seamless reconfiguration across a broad frequency range requires components that can operate effectively and reliably across multiple bands, which is a significant technical challenge.

Limited tuning range: Some RF components, such as varactor diodes, have limited tuning ranges (also referred to as tuning ratio). Varactor diodes are commonly used for voltage-controlled tuning, but their tuning range may not be sufficient to cover the desired frequency range of an RIS. This limitation restricts the achievable reconfigurability and hinders the full potential of RIS technology.

High losses: RF components used for reconfiguration in RIS often introduce significant signal losses. Losses can arise from various sources, including insertion loss, mismatch losses, and resistive losses in active components. High losses degrade the overall performance and efficiency of the RIS, affecting signal quality and range.

Power consumption: Reconfigurable RF components often consume significant power, especially active components like PIN diodes or RF switches. High power consumption not only increases the operational costs but also poses challenges in terms of heat dissipation and power supply requirements. Power-efficient solutions are necessary to ensure sustainable and practical implementation of RIS.

Integration challenges: Integrating reconfigurable RF components within the limited space and form factor of an RIS can be challenging. This is due to the unit-cell size in 5G and 6G applications are limited to roughly their half-wavelength (e.g., for 30 GHz, the maximum size is 5 mm*5 mm). The compact size and distributed nature of RIS require RF components that are small, lightweight, and compatible with the overall system design. Achieving seamless integration without compromising performance and reliability remains a significant engineering challenge.

### BRIEF DESCRIPTION OF THE DRAWINGS

In order to describe the manner in which at least some of the advantages and features of the invention may be obtained, a more particular description of embodiments of the invention will be rendered by reference to specific embodiments thereof which are illustrated in the appended drawings. Understanding that these drawings depict only typical embodiments of the invention and are not therefore to be considered to be limiting of its scope, embodiments of the invention will be described and explained with additional specificity and detail through the use of the accompanying drawings.

FIG. 1 discloses the functionality of Phase Change Materials (PCM);

FIGS. 2A and 2B disclose aspects of capacitors with a high SRF;

FIG. 3 discloses aspects of a panel of a reconfigurable intelligent surface (RIS);

FIGS. 4A-4C disclose aspects of a monolithically integrated capacitor bank;

FIG. 5 discloses aspects of a conventional varactor diode;

FIG. 6 discloses a comparison between a monolithically integrated capacitor bank and a conventional varactor diode; and

FIG. 7 discloses aspects of a computing device, system, or entity.

### DETAILED DESCRIPTION OF SOME EXAMPLE EMBODIMENTS

Embodiments of the present invention generally relate to reconfigurable intelligent surfaces. More particularly, at least some embodiments of the invention relate to systems, hardware, software, and methods for reconfigurable intelligent surfaces with a bank of capacitors that is monolithically integrated into the structure of the surface.

In general embodiments disclosed herein are related to a reconfigurable intelligent surface. The reconfigurable intelligent surface includes unit cells that include a bank of capacitors that is monolithically integrated into the structure of the reconfigurable intelligent surface. The bank of capacitors include a plurality of capacitors that have a high Self-Resonant Frequency (SRF). Each of the capacitors is integrated with a Phase Change Material (PCM) based radio frequency (RF) switch.

Embodiments of the invention, such as the examples disclosed herein, may be beneficial in a variety of respects. For example, and as will be apparent from the present disclosure, one or more embodiments of the invention may provide one or more advantageous and unexpected effects, in any combination, some examples of which are set forth below. It should be noted that such effects are neither intended, nor should be construed, to limit the scope of the claimed invention in any way. It should further be noted that nothing herein should be construed as constituting an essential or indispensable element of any invention or embodiment. Rather, various aspects of the disclosed embodiments may be combined in a variety of ways so as to define yet further embodiments. For example, any element(s) of any embodiment may be combined with any element(s) of any other embodiment, to define still further embodiments. Such further embodiments are considered as being within the scope of this disclosure. As well, none of the embodiments embraced within the scope of this disclosure should be construed as resolving, or being limited to the resolution of, any particular problem(s). Nor should any such embodiments be construed to implement, or be limited to implementation of, any particular technical effect(s) or solution(s). Finally, it is not required that any embodiment implement any of the advantageous and unexpected effects disclosed herein.

### A. Aspects of Phase Change Materials (PCM)

The embodiments disclosed herein implement phase change material switches. Accordingly, a discussion of phase change materials will now be given. Phase change materials are materials including chalcogenide materials formed with alloys containing group VI elements such as sulfur (S), selenium (Se) and telluride (Te). Other materials include germanium (Ge) and antimony (Sb). Among these, the germanium-telluride (GeTe) alloy is popular for RF and optical memory applications. Germanium-sulfide (Ges) may also be used. It will be appreciated that the embodiments disclosed herein are not limited to any particular PCM.

PCMs have a unique property of reversibly switching between amorphous and crystalline states upon specific heat treatment by means of electrical pulses. The state where atoms are arranged in a disorderly manner (short range order) is called the amorphous state, whereas the state where atoms are organized in an orderly manner (long range order) is called crystalline state. The disordered amorphous state has a lower mean free path of conduction for electrons that impedes current flow due to electron scattering, thus resulting in a higher resistance when compared to the crystalline state. Thus, the amorphous state may be considered a high resistive state, and the crystalline state may be considered a low resistive state.

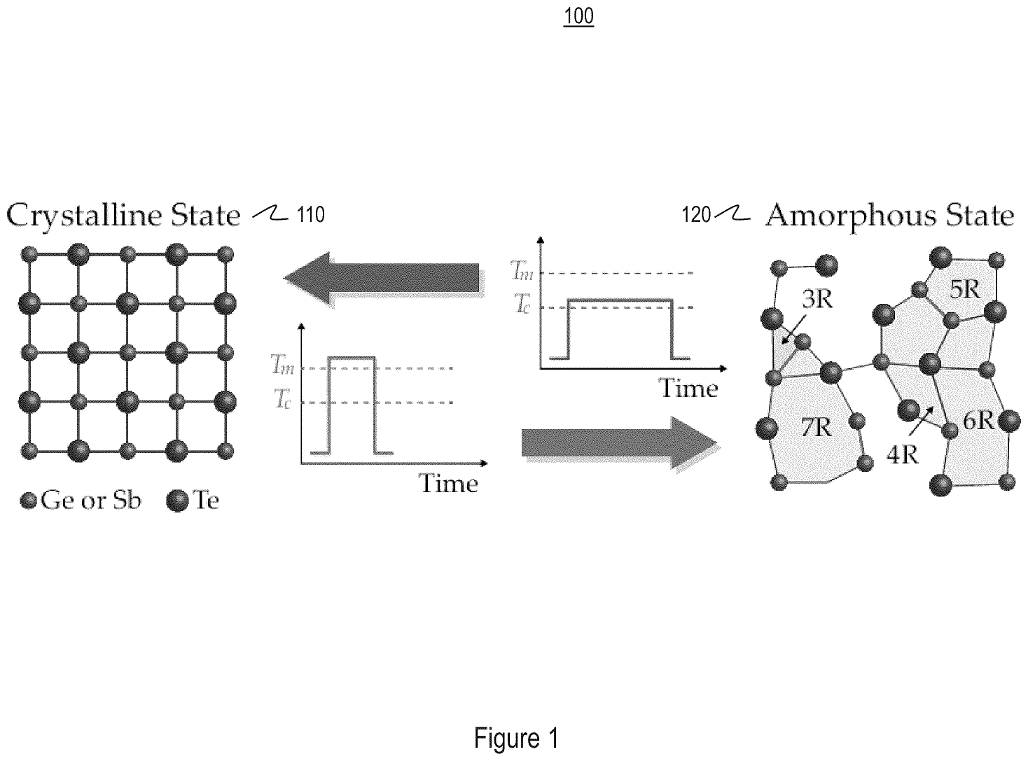

FIG. 1 shows a PCM 100. In the PCM 100, a medium amplitude (typically 1-2 V) and long duration (typically ^{˜}100 ns) SET electrical pulse (left directed arrow) is used for crystallization during a transition to the ON state. Energy from the SET pulse heats the material for sufficient time to crystallize the material and provides adequate time for atoms to reorganize to an orderly arrangement, thus transforming from an amorphous state 120 to crystalline state 110.

A short duration (typically <40 ns) and high amplitude (typically >2 V) RESET electrical pulse is used for re-amorphization. The RESET pulse (right directed arrow) provides sufficient energy to melt the material to disorder the atoms followed by rapid quenching to freeze the atoms, thus transforming the material from the crystalline state 110 to the amorphous state 120. Hence, just a short duration pulse is required to switch the state of the material and then it latches into that state, without the need for continuous power.

### B. Aspects of Capacitors with High Self-Resonant Frequency (SRF)

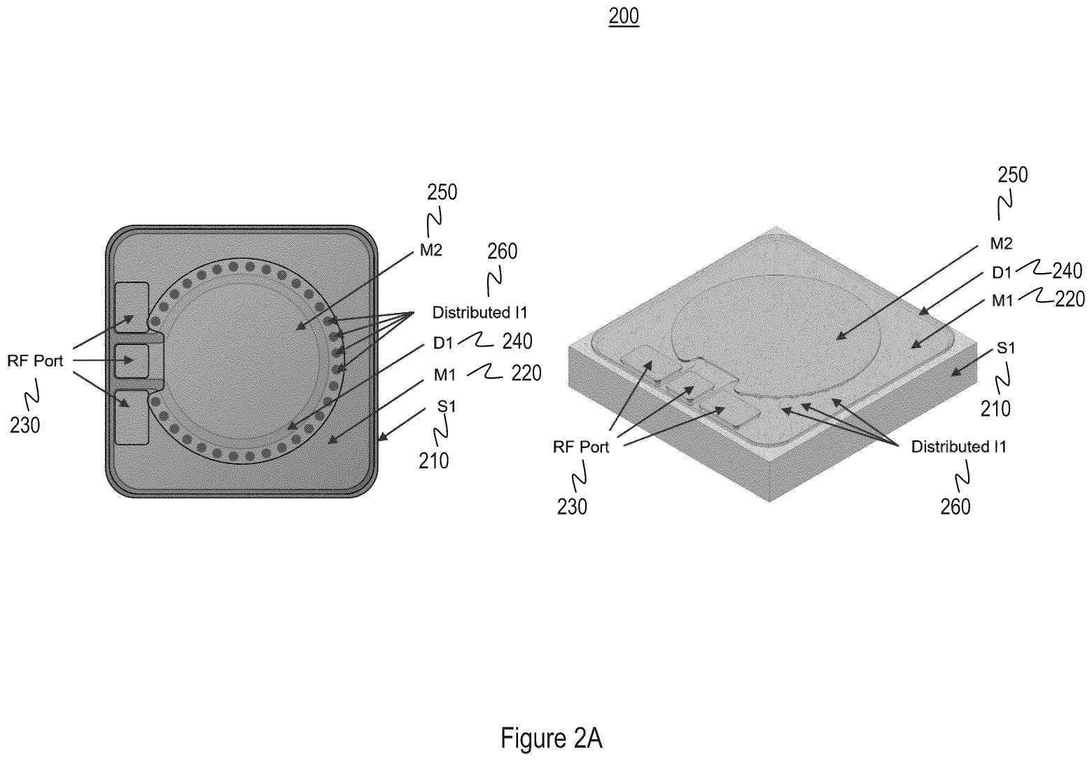

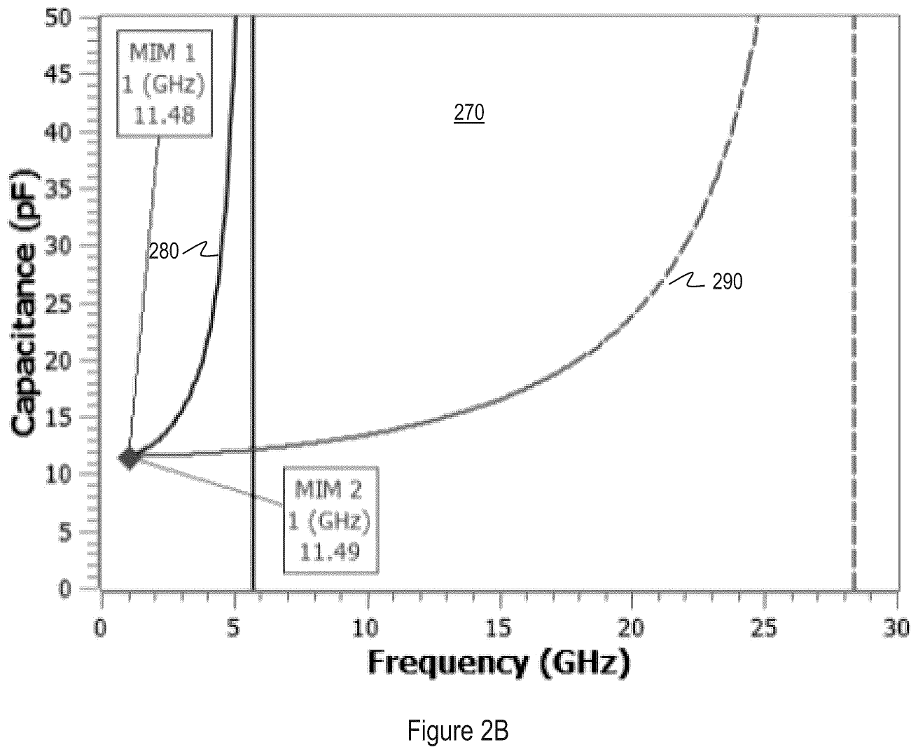

The embodiments disclosed herein implement capacitors with a high SRF. Accordingly, a discussion of an example embodiment of a capacitor with a high SRF will now be given in relation to FIGS. 2A and 2B. As shown, FIG. 2A illustrates an embodiment of an ultra-high-frequency metal-insulator-metal (MIM) capacitor 200 that is able to improve the SRF and Q-Factor while keeping the capacitor value constant. In general, MIM capacitors are a preferred choice to get high value of capacitance with tiny circuit footprint. The MIM capacitor 200 can be fabricated on printed circuit boards or on-chip.

FIG. 2A shows both a top view (left) and side view (right) of the embodiment of the MIM capacitor 200. As illustrated, the MIM capacitor 200 includes a substrate S1 210 that may be implemented as any reasonable substrate material. The other elements of the MIM capacitor 200 are patterned on the substrate 51210 using any reasonable method.

The MIM capacitor 200 includes a first metal plate M1 220 that is positioned on the top surface of the substrate S1 210. The first metal plate M1 220 can be made of any reasonable metal material such as copper.

An RF port 230 is positioned on the first metal plate M1 220 and can act as a waveguide in operation for receiving signals. A signal line gap D1 240 is also positioned on the first metal plate M1 220. In the embodiment, the signal line gap D1 240 is a circular ring, although such shape is not required as any other reasonable shape can also be used.

The MIM capacitor 200 includes a second metal plate M2 250 that is positioned above the first metal plater M1 220 and that can be made of any reasonable metal material such as copper. Various interconnects I1 260 are distributed around the capacitor area as shown in FIG. 2A. The interconnects I1 260 connect the first and second metal plates to each other.

The design of the MIM capacitor 200 is able to push the SRF of the capacitor to higher frequency values when compared to conventional capacitors. For example, as shown in FIG. 2B, a graph 270 shows capacitor values on the Y-axis and frequency on the X-axis. A curve 280 shows simulated results for a conventional capacitor. As illustrated, the conventional capacitor (labeled MIM1) has a value of 11.48 pF at 1 GHz. The value of the capacitor quickly increases as the frequency range goes higher and then reaches a SRF at around 5.8 GHz.

A curve 290 shows simulated results for the MIM capacitor 200. As illustrated, the MIM capacitor 200 (labeled MIM2) has a value of 11.49 pF at 1 GHz. The value of the capacitor only slowly increases as the frequency range goes higher and then reaches a SRF at around 28.2 GHz. Thus, the design of the MIM capacitor 200 is able to achieve an SRF at a much higher frequency and thus is able to be used in the embodiments disclosed herein. It will be noted, however, that the MIM capacitor 200 is only one example of a capacitor with high SRF that can be used. Thus, any capacitor having an SRF at high frequencies can be used in the embodiments disclosed herein and the embodiments disclosed herein and the claims are not limited by any specific type of capacitor having an SRF at high frequencies.

### C. Aspects of Reconfigurable Intelligent Surfaces (RIS)

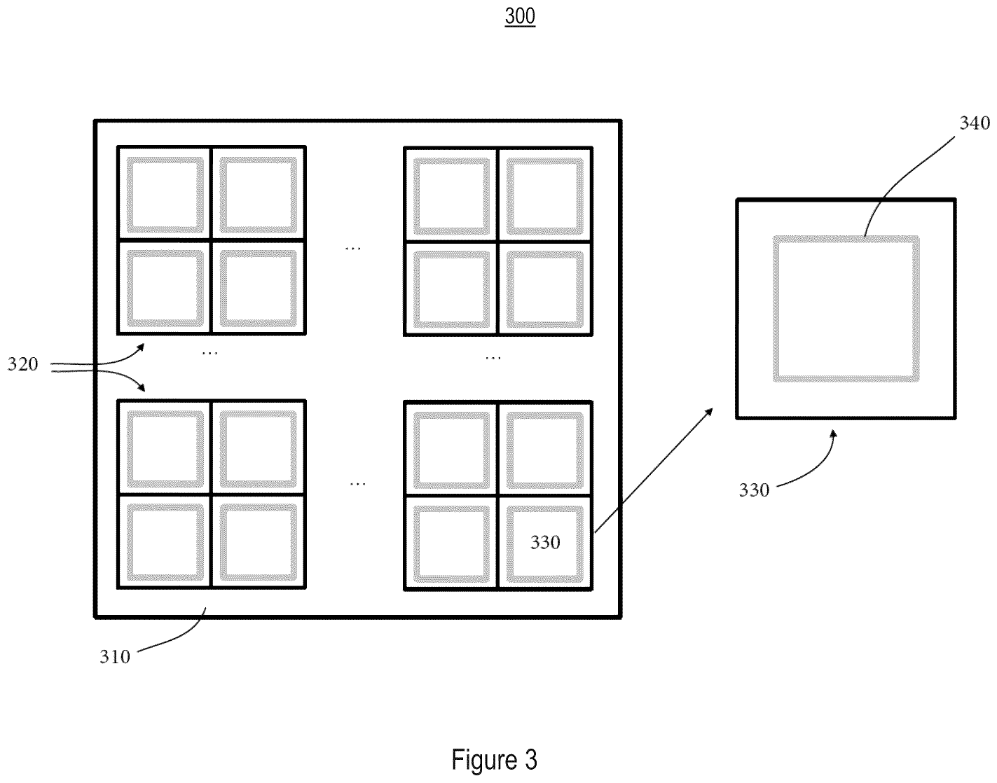

FIG. 3 discloses aspects of a panel of a reconfigurable intelligent surface (RIS). The RIS panel 300, which may be formed monolithically or formed using deposition, etching, and other techniques, includes a substrate 310 and an array 320 or other configuration of unit cells formed on a surface of the substrate 310. The unit cells, represented by the unit cell 330, each include a metal element 340.

The metal element 340 of the unit cell 330, which may be formed of copper, is independent of other metal elements on other unit cells in the array 320. The metal element 340 is typically arranged in a pattern (FIG. 3 illustrates a square metal element). The pattern may be sized, shaped, or otherwise arranged to be resonant with a particular frequency or range of frequencies. In one example, embodiments disclosed herein enable the panel 300 to be responsive to multiple frequencies or a range of frequencies.

### C.1. Monolithic Integration of Capacitor Banks

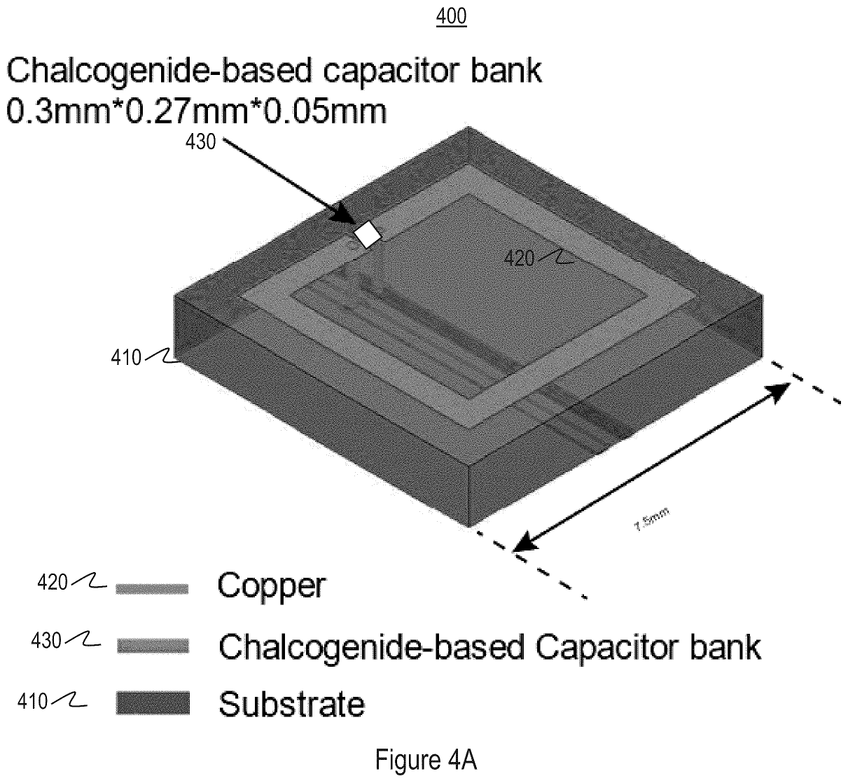

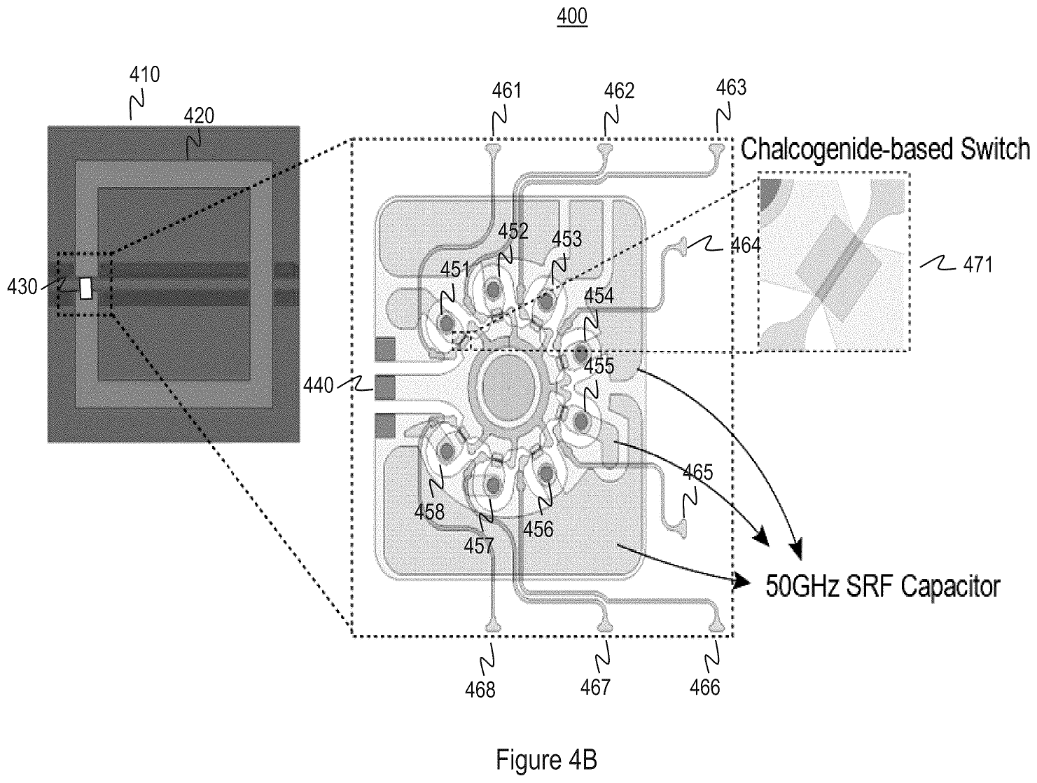

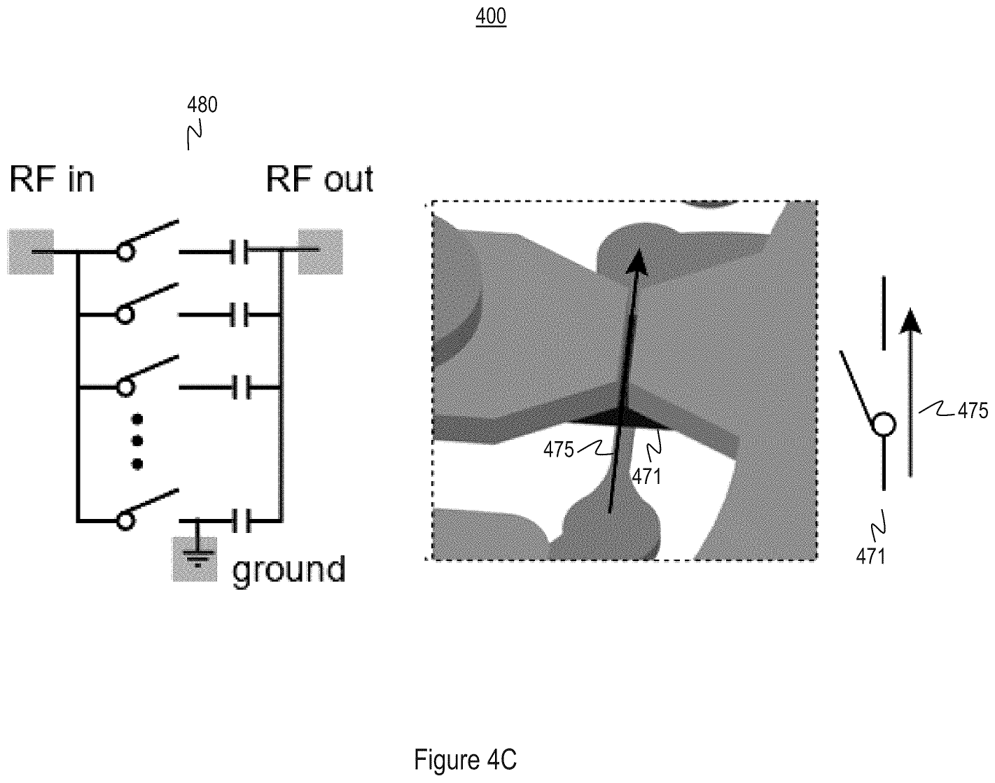

One novel aspect of the embodiments disclosed herein are related to the monolithic integration of capacitor banks onto a unit cell. FIG. 4A illustrates an embodiment of a unit cell 400 which corresponds to a unit cell 330 of the RIS panel 300. As illustrated, the unit cell 400 includes a dielectric substrate 410, which may correspond to the substrate 310. In one embodiment, the dielectric substrate 410 may be made of FR4, a type of printed circuit board material that may include epoxy resin and glass composite. However, in other embodiments the dielectric substrate 410 may be made of silicon, glass, sapphire, quartz, Rogers RF substrates, or any other suitable dielectric material.

The unit cell 400 also includes a metal element 420, which may correspond to the metal element 340. The metal element 420 is made of copper in the embodiment of FIG. 4A. However, in other embodiments other reasonable metals may be used. The metal element 420 is shown as being a square. However, the metal element may have other shapes as well. In general, the metallic element 420 is configured to have a shape such that the metallic element 420 is resonant with an incident signal or electromagnetic wave incident on the unit cell 400.

The unit cell 400 also includes a capacitor bank 430 that is monolithically integrated onto the substrate 410. In the embodiment of FIG. 4A, the monolithically integrated capacitor bank 430 is a chalcogenide-based capacitor bank. This means that the monolithically integrated capacitor bank 430 includes a chalcogenide-based switch as will be explained in more detail to follow. However, in other embodiments, the monolithically integrated capacitor bank 430 can have a switch that is integrated with a different type of phase change material (PCM) such as those discussed previously. As illustrated in FIG. 4A, the monolithically integrated capacitor bank 430 has the following dimensions: 0.3 mm×0.27 mm×0.05 mm.

FIG. 4B illustrates an expanded view of the monolithically integrated capacitor bank 430. As shown in the figure, the monolithically integrated capacitor bank 430 includes an RF port 440 that can act as a waveguide to input and output RF signals. In addition, the monolithically integrated capacitor bank 430 includes various capacitors. In the illustrated embodiment, the monolithically integrated capacitor bank 430 includes eight capacitors 451, 452, 453, 454, 455, 456, 457 and 458 that are arranged in a circular manner. Each of the capacitors 451, 452, 453, 454, 455, 456, 457 and 458 can all be implemented as capacitors having an SRF at different frequencies or to have different subsets of SRF frequencies. In the illustrated embodiment, the capacitors 455, 456, and 457 are implemented as 50 GHz SRF capacitors while the remaining capacitors are implemented to as capacitors having a different SRF frequency. In one embodiment, the capacitors 451, 452, 453, 454, 455, 456, 457 and 458 correspond to the MIM capacitor 200 previously described.

Each of the eight capacitors has an actuation mechanism for providing a pulse to the capacitor as will be explained in more detail to follow. Thus, the capacitor 451 has an actuation mechanism 461, the capacitor 452 has an actuation mechanism 462, the capacitor 453 has an actuation mechanism 463, the capacitor 454 has an actuation mechanism 464, the capacitor 455 has an actuation mechanism 465, the capacitor 456 has an actuation mechanism 466, the capacitor 457 has an actuation mechanism 467, and the capacitor 458 has an actuation mechanism 468.

Each of the capacitors 451, 452, 453, 454, 455, 456, 457 and 458 also have a PCM-based switch such as a chalcogenide-based switch. For ease of illustration, only the chalcogenide-based switch 471 of the capacitor 451 is shown. The operation of the chalcogenide-based switch 471 (and the other chalcogenide-based switches) will be explained in more detail to follow. Thus, any discussion herein related to the switch 471 would also apply to the PCM-based switch such as a chalcogenide-based switch of the other capacitors.

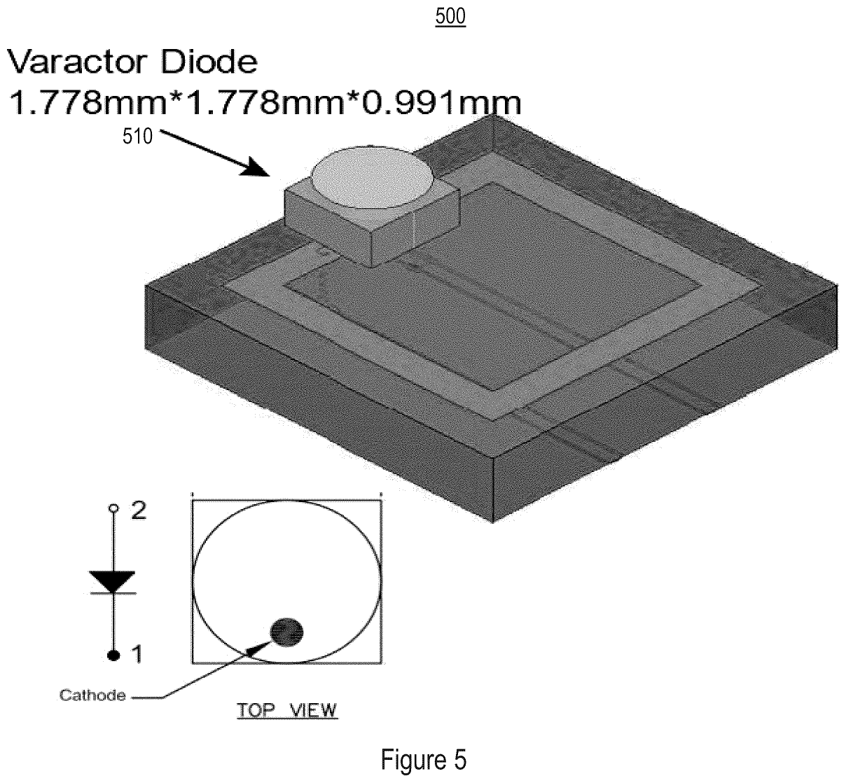

FIG. 5 illustrates a unit cell 500 according to a conventional design. In particular, the unit cell 500 implements a varactor diode 510 instead of the monolithically integrated capacitor bank of the current invention. As illustrated in FIG. 5, the varactor diode 510 has the following dimensions: 1.778 mm×1.778 mm×0.991 mm. When compared to the dimensions of the monolithically integrated capacitor bank 430 (0.3 mm×0.27 mm×0.05 mm) previously discussed, it can be seen that the monolithically integrated capacitor bank of the current invention provides a significant reduction in component size. This reduction in size in turn leads to a reduction in integration complexity. Further, it solves many of the problems discussed previously in regard to the size of surface mounted RF components at high frequencies. Integrating the capacitor bank monolithically also reduces the biasing complexity as the actuation signal network is built into the unit cell.

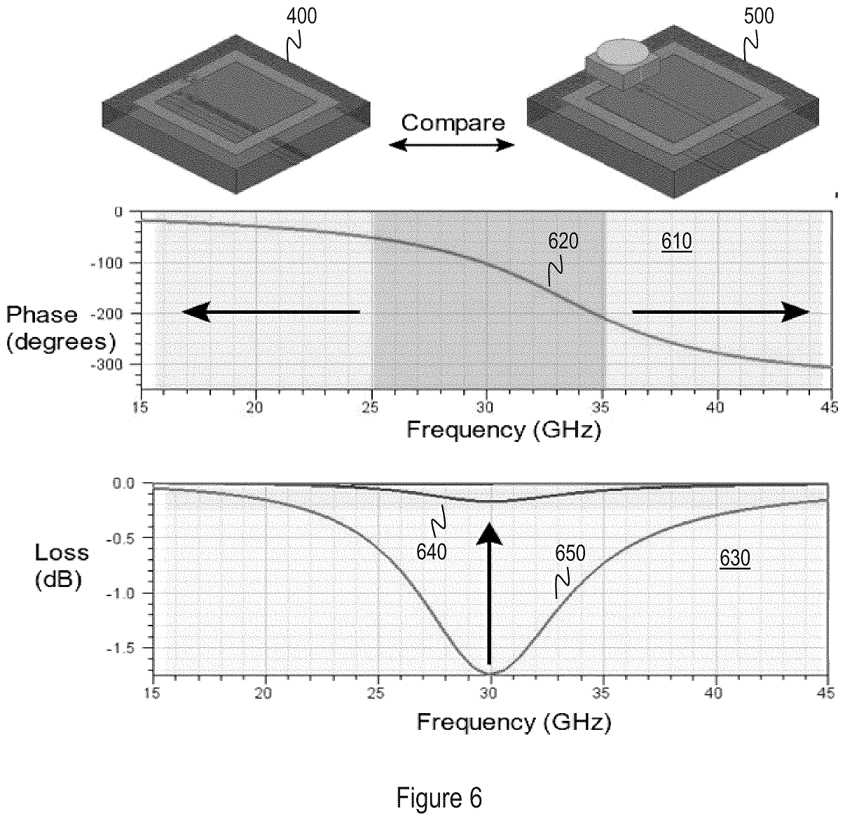

FIG. 6 illustrates further improvements of the unit cell 400 having the monolithically integrated capacitor bank 430 when compared to the unit cell 500 having the varactor diode 510. As illustrated in FIG. 6, a graph 610 shows phase on the Y-axis and frequency range on the X-axis. A curve 620 shows that the monolithically integrated capacitor bank 430 has a tunable range going from 15 GHz to 45 GHz. However, the varactor diode 510 is only tunable in a useable range from 25 GHz to 35 GHz. Thus, the monolithically integrated capacitor bank 430 has an improved frequency range when compared to conventional surface mounted RF components.

A graph 630 shows loss in dB on the Y-axis and frequency range on the X-axis. A curve 640 shows that in the useable range of 25 GHz to 35 GHz, the monolithically integrated capacitor bank 430 has very small loss. In contrast, in the useable range of 25 GHz to 35 GHz the varactor diode 510 has a significant amount of loss as shown by curve 650. Thus, the monolithically integrated capacitor bank 430 has improved performance when compared to conventional surface mounted RF components at high frequencies. Additional advantages of the monolithically integrated capacitor bank 430 when compared to conventional surface mounted RF components will be explained in more detail to follow.

### C.2. Use of PCM Based Switched in High SRF Capacitor Banks

Another novel aspects of the embodiments disclosed herein is related to the use of phase change material (PCM) based switches such as chalcogenide based switches. As previously discussed in relation to FIG. 4B, the capacitors 451, 452, 453, 454, 455, 456, 457 and 458 have a PCM-based switch such as the chalcogenide-based switch 471 of the capacitor 451. FIG. 4C shows an equivalent circuit 480 for each of the PCM-based switches of the capacitors 451, 452, 453, 454, 455, 456, 457 and 458. That is, each of the PCM-based switches can be opened or closed. When the switch is closed, the RF input signal will reach the capacitor and then be output to the RF out port. When the switch is opened, the RF signal will not reach the capacitor. Thus, by operating the PCM-based switches to select the capacitors having an SRF at a desired frequency, the reflective properties of the unit cell and the RIS panel it is part of can be controlled.

FIG. 4C also shows a close-up view of the chalcogenide-based switch 471. As mentioned previously, the actuation mechanisms 461-468 are integrated onto the unit cell for each capacitor. In operation, a first thermal pulse 475 is applied by the related actuation device to the desired PCM-based switches. The first thermal pulse 475 will change the phase change material of the switch from the amorphous state (i.e., the high restive state) to the crystalline state (i.e., the low restive state) when closing the PCM based switch so that the RF signal will reach the desired capacitors. A second thermal pulse 475, which will be a different shape than the first thermal pulse 475, is applied by the related actuation device to the desired PCM-based switches. The second thermal pulse 475 will change the phase change material of the switch from the crystalline state (i.e., the low restive state) to the amorphous state (i.e., the high restive state) to when opening the PCM based switch.

In some embodiments, this switching can be optimized to occur under sub-nanosecond times to fulfil the stringent specifications of 5G-Adv. and 6G communications. Compared to traditional switch technologies, such as mechanical switches or semiconductor-based switches, chalcogenide-based switches can be very easily controlled by just a small thermal pulse.

By leveraging optimized PCM-based switches such as chalcogenide-based switches in reconfigurable systems with proper planning and distribution of the bias network, power consumption can be minimized significantly. All the switches can be tied to a single voltage pad with common DC ground path leading to improved energy efficiency and longer battery life in portable devices. That is, there is no need for separate power to continually keep the switch in a closed state. Once the first thermal pulse is applied, the switch will stay in the closed state with no additional power needed until such time as the second thermal pulse is applied. Additionally, the reduced power consumption contributes to lower heat generation and overall system costs. The current invention of utilizing chalcogenide-based switches for reconfiguration not only enhances performance but also promotes sustainability and energy-conscious design in various applications, including wireless communication systems, IoT devices, and advanced sensor networks.

### D. Advantages

The use of monolithically integrated capacitor banks having a high SRF and having PCM-based switches have the following advantages over conventional surface mounted RF components such as PIN diodes or varactor diodes. It will be appreciated, however, that the following list of advantages is by no means the only advantages provided by the embodiments disclosed herein and thus the embodiments and the claims disclosed herein are not limited to particular advantages.

Extended Frequency Range (Much Higher Self Resonance Frequency): One significant advantage of PCM-based capacitor banks such chalcogenide-based capacitor banks (e.g., monolithically integrated capacitor bank 430) in RIS applications is their extended frequency range. These capacitor banks exhibit much higher self-resonance frequencies compared to traditional varactor diodes and PIN diodes. The self-resonance frequency represents the point at which the capacitor's reactive behavior transitions to become more dominant. By having a higher self-resonance frequency, PCM-based capacitor banks enable reconfiguration at much higher frequencies, expanding the operational range of the RIS. This is particularly beneficial in applications that require operation in the millimeter-wave or terahertz frequency bands, where traditional varactor diodes may not be suitable due to their limited frequency range.

Wider Tuning Range (Higher Capacitance Tuning Ratio): Another advantage of PCM-based capacitor banks is their wider tuning range. These capacitor banks offer a higher capacitance tuning ratio, allowing for greater control over the effective capacitance. By adjusting the capacitance value, the resonant frequency of the RIS can be modified, enabling frequency agility and reconfigurability. The wider tuning range of PCM-based capacitor banks compared to varactor diodes or PIN diodes provides more flexibility in adapting to different operational frequencies or communication standards. This increased tuning range is crucial for applications that require dynamic frequency selection, such as cognitive radio systems or software-defined radios. A comparison on SRF and tuning range of the chalcogenide-based capacitor banks (e.g., monolithically integrated capacitor bank 430) to commercially available RF varactor diodes is done below in table 1.

TABLE 1

| | Monolithic | | Tuning |
|---|---|---|---|
| Product name | Integration | SRF | ratio |
| Current Invention | Yes | Beyond 50 GHz | 58:1 |
| (monolithically integrated | | | |
| capacitor bank 430) | | | |
| Conventional Varactor | No | Beyond 20 GHz | 2:1 |
| Diode #1 | | | |
| Conventional Varactor | No | 10 GHz | 4.1:1 |
| Diode #2 | | | |
| Conventional Varactor | No | Not specified, tested | 2.6:1 |
| Diode #3 | | at 470 MHz | |

Lower Loss (One Order Higher Figure of Merit): PCM-based capacitor banks also offer lower loss compared to their semiconductor counterparts, such as GaN, GaAs, CMOS, and InP. The figure of merit (FOM), which quantifies the trade-off between capacitance and loss, is significantly higher in PCM-based materials. This translates to higher isolation and lower insertion loss in RIS systems. The reduced loss in PCM-based capacitor banks enhances the overall system performance by minimizing signal degradation and maximizing signal integrity. It is particularly advantageous for applications that require high-fidelity signal transmission, low noise figure, or high-quality communication links.

Improved Power Efficiency: PCM-based capacitor banks offer improved power efficiency compared to varactor diodes. These capacitor banks can achieve lower power consumption while maintaining their reconfigurability and performance characteristics. The inherent properties of PCM materials, such as high conductivity and low resistance, contribute to the improved power efficiency. The lower power consumption not only extends the battery life in portable devices but also reduces heat dissipation and overall system power requirements. This is crucial for energy-sensitive applications, such as IoT devices, wireless sensor networks, and battery-powered communication systems, where power efficiency is paramount.

Easier integration: Monolithically integrated components are fabricated directly on the substrate, eliminating the need for separate component packaging. This results in a more compact and space-efficient design, allowing for higher density integration of multiple components within a limited area. This is an advantage to RIS design as the compact integration is not only desirable for flexibility in reconfiguration when more components are required, but also essential for application in 6G which is 100 GHz-1 THz. The embodiments disclosed herein are unusable for 6G with the size constraint to maximum 3 mm.

Reduced Parasitic: Monolithically integrated components have shorter interconnects, leading to reduced parasitic elements such as inductance, capacitance, and resistance. This results in improved overall performance, lower losses, and enhanced electrical characteristics, especially at high frequencies.

Improved Performance: By integrating components on the same substrate, monolithically integrated unit cells can achieve better electrical and thermal coupling between the elements. This can lead to improved efficiency, enhanced signal integrity, and reduced power consumption.

Manufacturing and Reliability: Monolithic integration allows for a simplified manufacturing process since the components are fabricated together on a single substrate. This can result in improved yield, reduced assembly complexity, and enhanced reliability compared to the assembly of multiple surface mount components.

Frequency Bandwidth: Monolithically integrated components can provide broader frequency bandwidth due to the optimized layout and reduced parasitic. This is particularly beneficial for applications requiring wideband performance, such as in communication systems or RF/microwave circuits.

One application that may benefit from the utilization of reconfigurable intelligent reflective surfaces (RIS) according to the embodiment disclosed herein is the enhancement of indoor wireless coverage and capacity in 5G networks. By incorporating the novel aspects of monolithic integrated capacitor banks and reduced power consumption through PCM materials, the RIS technology presents significant advantages for improving indoor wireless communication systems.

The RIS acts as an intelligent surface comprising numerous small elements equipped with PCM-based monolithic integrated capacitor banks, enabling the dynamic reconfiguration of their electrical properties, such as capacitance. This reconfiguration capability allows the RIS to adaptively control and manipulate the incident electromagnetic waves, optimizing their propagation within indoor environments. PCM-based monolithic integrated capacitor banks offer an extended frequency range that encompasses the millimeter-wave and terahertz frequency bands, which are essential for indoor 5G communication systems. This broad frequency coverage enables the RIS to effectively manipulate and steer electromagnetic waves, enhancing signal quality and coverage in indoor environments.

The wider tuning range provided by the PCM-based monolithic integrated capacitor banks empowers the RIS to precisely adjust the reflected waves, enabling beamforming and interference mitigation. This capability allows for targeted signal delivery, overcoming obstacles and mitigating multipath effects within indoor spaces. Consequently, the RIS can significantly improve signal strength, reduce dead zones, and enhance overall wireless coverage and capacity in indoor environments.

The structure of the RIS disclosed herein also brings the advantage of lower loss, resulting in improved signal integrity and system performance. By reducing signal attenuation and improving the signal-to-noise ratio, the RIS can enhance the quality and reliability of indoor wireless communication links. Additionally, the reduced power consumption achieved through chalcogenide-based varactors contributes to energy-efficient indoor wireless communication systems. This is particularly vital for indoor environments, where power efficiency is a critical factor due to the deployment of numerous wireless devices and the need for sustainable and cost-effective operation.

Another application for the reconfigurable intelligent reflective surfaces (RIS) according to the embodiment disclosed herein is the deployment of wireless Internet of Things (IoT) networks in smart environments. With the increasing integration of IoT devices and sensors in various environments, the RIS according to the embodiment disclosed herein presents unique advantages for enhancing wireless connectivity and optimizing IoT network performance.

In smart environments such as smart homes, smart buildings, and smart cities, the deployment of wireless IoT networks is essential for collecting and transmitting data from numerous IoT devices and sensors. However, these environments often exhibit complex and dynamic radio frequency (RF) environments with multipath propagation, signal interference, and varying signal strengths. By incorporating the unit cells disclosed herein the RIS, the system gains the ability to adaptively control and manipulate the incident electromagnetic waves to suit the specific requirements of wireless IoT networks in smart environments. More specifically, it has the following advantages in the IoT network:

The extended frequency range offered by the proposed design allows the RIS to operate across a wide range of RF frequencies commonly used in IoT applications, such as the sub-GHz and GHz bands. This frequency agility enables the RIS to effectively manage and optimize wireless communication links between IoT devices and gateways, ensuring reliable and efficient data transmission.

The wider tuning range provided by PCM-based monolithically integrated capacitor banks allows the RIS to dynamically adjust the reflected waves and optimize signal paths in response to changing environmental conditions. This capability is particularly valuable in smart environments where RF interference and signal blockage may occur due to the presence of obstacles or dynamic objects.

The lower loss characteristic of PCM-based monolithically integrated capacitor banks improves the overall signal integrity and link quality within the wireless IoT network. By reducing signal attenuation and minimizing interference, the RIS enhances the reliability and robustness of wireless communication, enabling seamless connectivity and data transmission between IoT devices and the network infrastructure. Moreover, the reduced power consumption achieved through PCM-based monolithically integrated capacitor banks contributes to energy-efficient operation in wireless IoT networks. This is crucial for battery powered IoT devices that rely on efficient energy utilization to prolong battery life and minimize maintenance requirements.

By leveraging the advantages of PCM-based monolithically integrated capacitor banks in the RIS design, wireless IoT networks in smart environments can benefit from enhanced connectivity, improved coverage, and optimized network performance. The dynamic reconfiguration capability of the RIS enables adaptive signal control, allowing IoT devices to establish reliable and efficient communication links, even in challenging RF environments.

In general, embodiments of the invention may be implemented in connection with systems, software, and components, that individually and/or collectively implement, and/or cause the implementation of, signal processing operations, wireless coverage operations, signal steering or reflection operations, wireless coverage operations, or the like. More generally, the scope of the invention embraces any operating environment in which the disclosed concepts may be useful.

It is noted that any operation of any of the methods disclosed herein may be performed in response to, as a result of, and/or, based upon, the performance of any preceding operation. Correspondingly, performance of one or more operations, for example, may be a predicate or trigger to subsequent performance of one or more additional operations. Thus, for example, the various operations that may make up a method may be linked together or otherwise associated with each other by way of relations such as the examples just noted. Finally, and while it is not required, the individual operations that make up the various example methods disclosed herein are, in some embodiments, performed in the specific sequence recited in those examples. In other embodiments, the individual operations that make up a disclosed method may be performed in a sequence other than the specific sequence recited.

### E. Further Example Embodiments

Following are some further example embodiments of the invention. These are presented only by way of example and are not intended to limit the scope of the invention in any way.

Embodiment 1. A reconfigurable intelligent surface comprising: a substrate; a metal element formed on the substrate; a capacitor bank that is monolithically integrated with the substrate, the capacitor bank having a plurality of capacitors having a Self-Resonant Frequency (SRF) of at least 20 GHz; and a plurality of Phase Change Material (PCM)-based radio frequency (RF) switches integrated with each of the plurality of capacitors.

Embodiment 2. The reconfigurable intelligent surface of embodiment 1, wherein the plurality of PCM-based switches are a configured to change from the high resistive state to the low resistive state in response to a first thermal pulse and change from a low resistive state to a high resistive state in response to a second thermal pulse.

Embodiment 3. The reconfigurable intelligent surface of any previous embodiment, wherein the phase change material comprises a chalcogenide material.

Embodiment 4. The reconfigurable intelligent surface of any previous embodiment, further comprising: a plurality of actuation mechanisms corresponding to each of the plurality of capacitors.

Embodiment 5. The reconfigurable intelligent surface of any previous embodiment, wherein the first thermal pulse and the second thermal pulse are received from the plurality of actuation mechanisms.

Embodiment 6. The reconfigurable intelligent surface of any previous embodiment, wherein the PCM-based switches remain in the low resistive state until receiving the second thermal pulse without the need for any additional power source.

Embodiment 7. The reconfigurable intelligent surface of any previous embodiment, wherein the plurality of capacitors have an SRF in a range between 20 GHz and 50 GHz.

Embodiment 8. The reconfigurable intelligent surface of any previous embodiment, wherein the plurality of capacitors have an SRF above 50 GHz.

Embodiment 9. The reconfigurable intelligent surface of any previous embodiment, wherein the capacitor bank that is monolithically integrated with the substrate has a tuning ratio of 58:1.

Embodiment 10. The reconfigurable intelligent surface of any previous embodiment, wherein the reconfigurable intelligent surface does not implement any surface mounted RF components.

Embodiment 11. A reconfigurable intelligent surface comprising: a substrate comprising a plurality of unit cells, wherein each of the unit cells comprises: a metal element formed on the substrate; a capacitor bank that is monolithically integrated with the substrate, the capacitor bank having a plurality of capacitors having a Self-Resonant Frequency (SRF) of at least 20 GHz; and a plurality of Phase Change Material (PCM)-based radio frequency (RF) switches integrated with each of the plurality of capacitors.

Embodiment 12. The reconfigurable intelligent surface of any previous embodiment, wherein the plurality of PCM-based switches are a configured to change from the high resistive state to the low resistive state in response to a first thermal pulse and change from a low resistive state to a high resistive state in response to a second thermal pulse.

Embodiment 13. The reconfigurable intelligent surface of any previous embodiment, wherein the phase change material comprises a chalcogenide material.

Embodiment 14. The reconfigurable intelligent surface of any previous embodiment, further comprising: a plurality of actuation mechanisms corresponding to each of the plurality of capacitors.

Embodiment 15. The reconfigurable intelligent surface of any previous embodiment, wherein the first thermal pulse and the second thermal pulse are received from the plurality of actuation mechanisms.

Embodiment 16. The reconfigurable intelligent surface of any previous embodiment, wherein the PCM-based switches remain in the low resistive state until receiving the second thermal pulse without the need for any additional power source.

Embodiment 17. The reconfigurable intelligent surface of any previous embodiment, wherein the plurality of capacitors have an SRF in a range between 20 GHz and 50 GHz.

Embodiment 18. The reconfigurable intelligent surface of any previous embodiment, wherein the plurality of capacitors have an SRF above 50 GHz.

Embodiment 19. The reconfigurable intelligent surface of any previous embodiment, wherein the capacitor bank that is monolithically integrated with the substrate has a tuning ratio of 58:1.

Embodiment 20. The reconfigurable intelligent surface of any previous embodiment, wherein the reconfigurable intelligent surface does not implement any surface mounted RF components.

Embodiment 21. A non-transitory storage medium having stored therein instructions that are executable by one or more hardware processors to perform operations comprising the operations of any one or more of embodiments disclosed herein.

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

By way of example, and not limitation, such computer storage media may comprise hardware storage such as solid state disk/device (SSD), RAM, ROM, EEPROM, CD-ROM, flash memory, phase-change memory or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality of the invention. Combinations of the above should also be included within the scope of computer storage media. Such media are also examples of non-transitory storage media, and non-transitory storage media also embraces cloud-based storage systems and structures, although the scope of the invention is not limited to these examples of non-transitory storage media.

Computer-executable instructions comprise, for example, instructions and data which, when executed, cause a general purpose computer, special purpose computer, or special purpose processing device to perform a certain function or group of functions. As such, some embodiments of the invention may be downloadable to one or more systems or devices, for example, from a website, mesh topology, or other source. As well, the scope of the invention embraces any hardware system or device that comprises an instance of an application that comprises the disclosed executable instructions.

As used herein, the term module, component, engine, agent, service, or the like may refer to software objects or routines that execute on the computing system. These may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments of the invention may be performed in client-server environments, whether network or local environments, or in any other suitable environment. Suitable operating environments for at least some embodiments of the invention include cloud computing environments where one or more of a client, server, or other machine may reside and operate in a cloud environment.

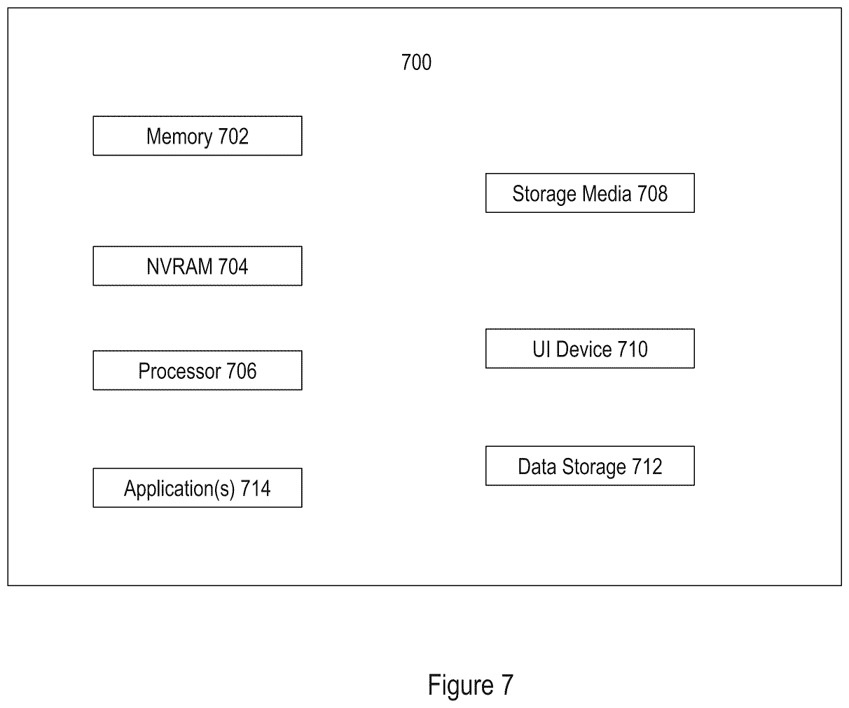

With reference briefly now to FIG. 7, any one or more of the entities disclosed, or implied, by the Figures and/or elsewhere herein, may take the form of, or include, or be implemented on, or hosted by, a physical computing device, one example of which is denoted at 700. As well, where any of the aforementioned elements comprise or consist of a virtual machine (VM), that VM may constitute a virtualization of any combination of the physical components disclosed in FIG. 7.

In the example of FIG. 7, the physical computing device 700 includes a memory 702 which may include one, some, or all, of random access memory (RAM), non-volatile memory (NVM) 704 such as NVRAM for example, read-only memory (ROM), and persistent memory, one or more hardware processors 706, non-transitory storage media 708, UI device 710, and data storage 712. One or more of the memory components 702 of the physical computing device 700 may take the form of solid state device (SSD) storage. As well, one or more applications 714 may be provided that comprise instructions executable by one or more hardware processors 706 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A reconfigurable intelligent surface comprising:
a substrate;
a metal element formed on the substrate;
a capacitor bank that is monolithically integrated with the substrate, the capacitor bank having a plurality of capacitors having a Self-Resonant Frequency (SRF) of at least 20 GHz; and
a plurality of Phase Change Material (PCM)-based radio frequency (RF) switches integrated with each of the plurality of capacitors.

2. The reconfigurable intelligent surface of claim 1, wherein the plurality of PCM-based switches are configured to change from a high resistive state to a low resistive state in response to a first thermal pulse and change from the low resistive state to the high resistive state in response to a second thermal pulse.

3. The reconfigurable intelligent surface of claim 2, wherein the phase change material comprises a chalcogenide material.

4. The reconfigurable intelligent surface of claim 2, further comprising:
a plurality of actuation mechanisms corresponding to each of the plurality of capacitors.

5. The reconfigurable intelligent surface of claim 4, wherein the first thermal pulse and the second thermal pulse are received from the plurality of actuation mechanisms.

6. The reconfigurable intelligent surface of claim 2, wherein the PCM-based switches remain in the low resistive state until receiving the second thermal pulse without a need for any additional power source.

7. The reconfigurable intelligent surface of claim 1, wherein the plurality of capacitors have an SRF in a range between 20 GHz and 50 GHz.

8. The reconfigurable intelligent surface of claim 1, wherein the plurality of capacitors have an SRF above 50 GHz.

9. The reconfigurable intelligent surface of claim 1, wherein the capacitor bank that is monolithically integrated with the substrate has a tuning ratio of 58:1.

10. The reconfigurable intelligent surface of claim 1, wherein the reconfigurable intelligent surface does not implement any surface mounted RF components.

11. A reconfigurable intelligent surface comprising:
a substrate comprising a plurality of unit cells, wherein each of the unit cells comprises:
a metal element formed on the substrate;
a capacitor bank that is monolithically integrated with the substrate, the capacitor bank having a plurality of capacitors having a Self-Resonant Frequency (SRF) of at least 20 GHz; and
a plurality of Phase Change Material (PCM)-based radio frequency (RF) switches integrated with each of the plurality of capacitors.

12. The reconfigurable intelligent surface of claim 11, wherein the plurality of PCM-based switches are configured to change from a high resistive state to a low resistive state in response to a first thermal pulse and change from the low resistive state to the high resistive state in response to a second thermal pulse.

13. The reconfigurable intelligent surface of claim 12, wherein the phase change material comprises a chalcogenide material.

14. The reconfigurable intelligent surface of claim 12, further comprising:
a plurality of actuation mechanisms corresponding to each of the plurality of capacitors.

15. The reconfigurable intelligent surface of claim 14, wherein the first thermal pulse and the second thermal pulse are received from the plurality of actuation mechanisms.

16. The reconfigurable intelligent surface of claim 12, wherein the PCM-based switches remain in the low resistive state until receiving the second thermal pulse without a need for any additional power source.

17. The reconfigurable intelligent surface of claim 11, wherein the plurality of capacitors have an SRF in a range between 20 GHz and 50 GHz.

18. The reconfigurable intelligent surface of claim 11, wherein the plurality of capacitors have an SRF above 50 GHz.

19. The reconfigurable intelligent surface of claim 11, wherein the capacitor bank that is monolithically integrated with the substrate has a tuning ratio of 58:1.

20. The reconfigurable intelligent surface of claim 11, wherein the reconfigurable intelligent surface does not implement any surface mounted RF components.
